(19) United States
(12) Patent Application Publication
(10) Pub. No.: US 2018/0237906 A1
(43) Pub. Date: Aug. 23, 2018

(54) PROCESS CHAMBER SHIELDING SYSTEM AND METHOD

(71) Applicant: NOVENA TEC INC., Markham (CA)

(72) Inventors: Rommel MONTES, Calgary (CA); Rajan THIRU, Markham (CA); Ravi THIRUN, Markham (CA)

(73) Assignee: NOVENA TEC INC., Markham, ON (CA)

(21) Appl. No.: 15/754,255

(22) PCT Filed: Jun. 13, 2016
(86) PCT No.: PCT/CA2016/050675

§ 371 Date: Feb. 21, 2018

Related U.S. Application Data
(60) Provisional application No. 62/208,613, filed on Aug. 22, 2015.

(51) Int. Cl. C23C 14/56; C23C 16/44; B05D 1/32

(52) U.S. Cl. CPC C23C 14/564; B05D 1/322; C23C 16/4401

(57) ABSTRACT

A removable coating for protecting process chamber components from excess material resulting from operation of a process chamber. The removable coating including a sheet. A bonding surface of the sheet to be releasably bonded to a process chamber component to be protected. A deposition surface of the coating selected to receive and retain the excess material. In an aspect, the coating may further include a deposition layer bonded to a sheet surface in opposition to the bonding surface. The deposition layer providing the deposition surface. In some aspects the deposition surface may be provided of a different material from the process chamber component. In some aspects, and method and system are provided for protecting process chamber components.

### CROSS-REFERENCE TO RELATED APPLICATION

This application claims priority to U.S. Provisional Patent Application Ser. No. 62/208,613 filed on Aug. 22, 2015, the contents of which are incorporated entirely herein by reference.

### FIELD OF THE INVENTION

The following relates generally to process chambers for thin film deposition in semiconductor fabrication, and more particularly an improved system and method for shielding the various components of a process chamber.

### BACKGROUND OF THE INVENTION

Physical vapour deposition (PVD), otherwise known as sputtering, is a process by which a film may be deposited on a substrate during the fabrication of semiconductors. PVD is a plasma process conducted within a vacuum process chamber, and involves bombarding a target with ions to cause the target to eject atoms. The ejected atoms build up as a deposited film on an intended semiconductor substrate being supported within the process chamber.

Chemical Vapour Deposition (CVD) is a process used to produce high quality, high-performance, solid materials. The process is often used in the semiconductor industry to produce very uniform thin film deposition. This thin film deposition is generated by higher temperature, pressure, and plasma causing a chemical reaction.

Excess material tends to also deposit on various parts of the apparatus, such as the showerhead and other parts within the process cavity, excess material during the process resulting from overspray of the released material condensing and accumulating in the chamber during operation. The excess material tends to create a thin excess material film on interior surfaces of the process chamber. Over time, ejected atoms can land on, and build up over, other components within the process chamber that are not intended to receive deposition, such as shielding components (commonly referred to as “process kit components”) including a sidewall shields, bottom shield, outer and inner shields, deposition rings, cover ring, dummy wafer and any other shielding components that define the process chamber cavity, as well as on the pedestal supporting an intended substrate, and heater that heats the substrate.

Build-up of the excess material film on the heater can negatively affect the heater's ability to control heat of the intended substrate and is expensive to clean. Furthermore, the undesirable excess material film build-upon the heater and other process chamber components can thicken over time to a point that mechanical stresses within the excess material film may cause the excess material film to weaken and pieces or flakes of the film eventually break away into the process chamber and come into contact with a substrate where a new deposition is being attempted. Typically, material may flake off during changes in the process environment such as during wafer transfer operations, or quick pressure changes induced by switching gas flow.

These unwanted flakes interfere and contaminate with the deposition process and can result in serious degradation of the quality of the new thin film that is intended to be deposited on the wafer. As such, in order to maintain quality of deposited films, it is well known from time to time to take the process chamber temporarily out of service for cleaning by removing excess material film that has built up on process chamber components since the last cleaning

In order to ease the cleaning process, and also to block flakes of built-up excess material film from reaching the vicinity of the intended substrate, it is well-known to employ a collection of components called a process kit within the process chamber. The process kit components are shielding components that are generally removably positioned within the process chamber and are configured in shape and size to both channel the ejected atoms towards the substrate and to somewhat shield more permanent structural components of the process chamber including the process chamber walls from excess material film build-up. Because the process kit components are removable they may be removed from the process chamber for cleaning, and replaced with clean process chamber components so that the process chamber may more quickly be put back into service.

It is known to treat the surfaces of process kit components by abrading the surfaces using arc spray or bead blasting to enhance the ability for stray ejected atoms to adhere to the process kit components, creating a more stable excess material film on the process kit component surfaces. The goal being to present a receptive roughened surface that provides a stable substrate for building a thin excess material film of the atoms, increasing the useful operational run life of the components during which the excess material film is stable and does not flake away in the process chamber during operation. Treating the process kit components surfaces in this manner provides for longer intervals between cleanings The surface treatment improves the stability of the excess material film, allowing for longer operational runs, but does not eliminate the need to periodically remove the excess material film from the process chamber.

Typically, the excess material film may be removed from the process chamber by removing the shielding components from the process chamber after the useful operational run life and replacing them with new/clean shielding components. In some cases, the process chamber walls may also require cleaning to remove built-up excess material using techniques such as polishing, bead blasting, and/or chemical/electro-chemical treatment.

The used shielding components may either be discarded for recycling, or in some cases may be treated to clean their surfaces. In cases where the shielding components are cleaned, the used shielding components are typically treated by polishing, bead blasting, and/or chemical/electro-chemical treatment. After removal of the excess material film, the surface treatment may be re-administered to the component surfaces for re-use of the cleaned and treated process kit component. Since the shielding components are generally of lighter gauge than the process chamber walls there is a limited operational life, number of process and subsequent cleaning cycles, until a shielding component must be discarded. Furthermore, the cleaning process is time consuming, typically requiring rotation of one or more process kits in service while previously used process kits are off-line during the cleaning process.

There is a need for a process chamber shielding system and method that avoids limitations of the prior art.

### SUMMARY OF THE INVENTION

In an aspect, a removable coating for protecting process chamber components from excess material is provided. The removable coating may include a sheet. A bonding surface of the sheet for bonding to a process chamber component and a deposition surface of the coating selected to receive the excess material. In an aspect, the coating may further include a deposition layer bonded to a surface of the sheet in opposition to the bonding surface, and providing the deposition surface. The deposition layer may be formed, for instance, by anodizing, plasma coating, or spray coating material onto the sheet. In an implementation, the deposition surface may be treated to impart a deposition texture into the deposition surface for improving the reception and retention of the excess material on the deposition surface.

In an aspect of the removable coating, the bonding surface is treated to provide a bonding texture in the bonding surface for reducing a contact area between the sheet and the process chamber component during bonding. The reduced contact area may reduce a bonding strength between the coating and the process chamber component. The reduced contact area may provide for a lower heat transfer rate between the coating and the process chamber component.

In an aspect of the removable coating, the coating may further comprise a deposition layer bonded to a sheet surface in opposition to the bonding surface. The deposition layer providing the deposition surface for receiving the excess material. The deposition surface may comprise a deposition texture impressed into the deposition layer to present a receptive surface for receiving and retaining the excess material.

In an aspect of the removable coating, the bonding surface may be treated to impart a bonding texture into the bonding surface. The bonding texture reducing a contact area between the sheet and the process chamber component across the releasable bond.

In an aspect, the treatment may comprise rolling or pressing the coating to impress the deposition texture into the deposition surface. In an aspect, the treatment may comprise rolling or pressing the coating to impress the bonding texture into the bonding surface. In an aspect, the bonding treatment applied to the bonding surface is the same as the treatment applied to the deposition surface. In an aspect a different treatment is applied to each of the bonding surface and the deposition surface.

In an implementation of the removable coating the sheet is between 30 μm to 10 mm thick, and the deposition layer is between 5 nm to 1000 μm. In an implementation the sheet and the deposition layer comprise a same material. In an implementation the sheet and the deposition layer may comprise a different material. In an aspect, the deposition layer comprises a metal.

In an aspect a process chamber is provided. The process chamber having walls, a base, and a cover defining a process chamber cavity. The process chamber cavity includes a pedestal and heater for supporting a substrate (e.g. a wafer) to receive a deposition material. The process chamber may further include at least one shielding component located to shield an interior wall surface of the process chamber from excess material resulting from deposition of the deposition material onto the substrate. The process chamber further includes a removable coating releasably bonded to at least one interior surface of the process chamber. The removable coating adapted to receive and retain excess material of the deposition material resulting from operation of the process chamber, and adapted to be removed from the at least one interior surface by breaking the releaseable bond between the removable coating and the at least one interior surface. In an aspect, the removable coating is releasably bonded to the at least one shielding component. In an aspect, the removable coating is releasably bonded to an interior wall of the process chamber.

In an aspect of the process chamber, the removable coating may comprise a sheet having a bonding surface for releasably bonding to the at least one interior surface. In an aspect, the removable coating may further comprise a deposition surface on a sheet surface of the sheet in opposition to the bonding surface. In an aspect, the deposition surface may comprise an exposed surface of a film bonded to the sheet surface of the sheet, the exposed surface of the film providing the deposition surface selected to receive the excess material. In an aspect the deposition surface may comprise a treated surface, for instance by machining, pressing, or chemical etching, the treated surface adapted to receive and retain the excess material.

A method for coating a process chamber component comprising providing a removable coating for protecting the process chamber component from excess material. The removable coating comprising a sheet, a bonding surface of the sheet for bonding to a process chamber component. The coating may further comprise a deposition surface selected to receive the excess material. The method may further comprise bonding the removable coating by conforming the removable coating to a surface of the process chamber component intended to be protected, and spot welding the removable coating to the process chamber component.

In an aspect, a method is provided for cleaning a process chamber component coated with an excess material after completing an operational cycle within a process chamber. The method comprising removing a removable coating releasably bonded to the process chamber component, the removable coating having captured the excess material and, bonding a replacement removable coating to the process chamber component by conforming the replacement removable coating to a surface of the process chamber component intended to be protected, and spot welding the replacement removable coating to the process chamber component.

In an aspect of the method, the deposition surface of the replacement removable coating comprises a different material from the removed removable coating. In an aspect of the method, before the bonding of the replacement removable coating to the process chamber component, the method further comprises treating at least one of the bonding surface and the deposition surface to a surface treatment intended to either improve a bonding of the bonding surface to the process chamber component or to improve the capture and retention of excess material on the deposition surface.

In an aspect the treating comprises bead blasting or arc spraying the deposition surface of the removable coating and/or the replacement removable coating. In an aspect the treating comprises passing the coating through a roller or a press to impress one of a pattern or an irregular surface. In an aspect, the treating comprises treating both the bonding surface and the deposition surface of the coating. In an aspect the treating comprises machining the deposition surface of the removable coating and/or the replacement removable coating.

According to another aspect of the invention, there is provided a process kit component comprising a base dimensioned to be positioned within a semiconductor process chamber with respect to an intended deposition substrate; and a removable coating for shielding the base, the removable coating comprising a metal sheet layer conforming to at least a portion of the base; and a coating layer affixed to and conforming to the metal sheet, the coating having a enhanced bonding strength between metal sheet layer and deposition material there across, wherein the removable coating is selectively removable from the base.

In an aspect, the coating layer having a treated deposition surface that preferentially receives and “holds” excess material in the form of ejected atoms and the resultant excess material film build-up without immediate flaking of the film. This can result in significant defect reduction, and also enables an operator to increase the time between cleanings as compared with smoother process kit component surfaces. During cleanings, the removable coating may be removed, discarded and entirely replaced by a replacement removable coating of the same or similar nature. As compared with cleaning of a process kit component whose actual surface is the recipient of treatment by bead blasting or aluminum arc spraying, or with the re-application of such surface treatment, simply encapsulating the process kit component or portion thereof with a replacement removable coating takes far less time to achieve. As such, the process chamber can be quickly cleaned and put back in service.

A replacement removable coating may have the same amount of generally-uniform roughness as the removable coating it is replacing. Alternatively, such a replacement removable coating may increase or reduce the roughness depending on the thickness of deposition material. Various replacement sheets could be made available in order to provide a selection of roughness levels for use in various stages of deposition where higher or lower stress films are being deposited.

In an embodiment, the removable coating may comprise a ceramic coating. Ceramic process chamber surfaces are preferentially used for higher temperature processes, such as CVD. The ceramic coating may comprise one or more metal weld points embedded in the ceramic and exposed on the bonding surface. The metal weld points of the ceramic removable coating may similarly be spot welded to the process chamber or process component. In an aspect, the deposition surface of the ceramic coating may be treated by machining to obtain a desired surface roughness.

Other aspects and advantages will become apparent from the following description.

### BRIEF DESCRIPTION OF THE DRAWINGS

Embodiments will now be described with reference to the appended drawings in which:

FIG. 1 is aside cross-section view of an exemplar prior art process chamber.

FIG. 2 is a side cross-section view of the process chamber of FIG. 1, further including an embodiment of a shield coating.

FIG. 3 A is a side section view of an embodiment of a coating.

FIG. 3 B is a side section view of an embodiment of a coating.

FIG. 4 A is a side section view of an embodiment of a coating.

FIG. 4 B is a side section view of an embodiment of a coating.

FIG. 4 C is a side section view of an embodiment of a coating.

FIG. 4 D is a side section view of an embodiment of a coating.

FIG. 4 E is a side section view of an embodiment of a coating.

FIG. 4 F is a side section view of an embodiment of a coating.

### DETAILED DESCRIPTION

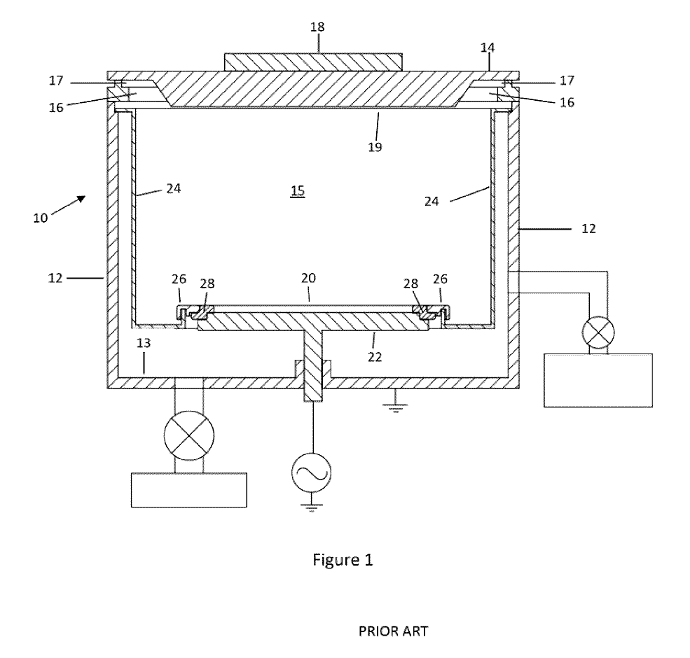

Referring to FIG. 1, a cross-section of an exemplar prior art process chamber 10 is illustrated. The process chamber 10 includes a chamber body defined by chamber walls 12, base 13 and cover 14. The chamber body defines a chamber cavity 15 in which the process is contained. The chamber walls 12 and base 13 are commonly constructed in fixed arrangement to one another with the cover 14 being removable. Typically, a sealing ring 16 and sealing gasket 17 are provided to assist with securing the cover 14 in sealing engagement with the walls 12. A magnet 18 is provided above the cover 14 to work in cooperation with a target 19 located on the inside of the cover 14 to generate material to be deposited on a substrate.

Below the target 19 a pedestal 22 is provided for supporting the wafer 20 to be coated in the process chamber 10. Typically, a heater is located beneath, or within, the pedestal 22 for heating the substrate (wafer 20) and the chamber cavity 15. As illustrated in FIG. 1, shielding components, i.e. process kit components, are provided to shield the walls 12, base 13, and pedestal 22 from deposition of excess material. In the exemplary FIG. 1, the shielding components include an inner shield 24 for shielding the walls 12. The inner shield 24 may further shield the base 13 when working in cooperation with the cover ring 26. A deposition ring 28 further seals edges of the pedestal 20 and the heater 22.

As will be appreciated, the illustrated shielding components are for illustrative purposes only, and other combinations of shielding components may be employed for a particular process chamber 10. As described above, the purpose of the shielding components is to block deposition of material onto parts of the process chamber 10. Standard semiconductor process chambers employ shielding components of a variety of materials including metals (such as stainless steel and aluminum), high purity ceramic parts, and quartz parts.

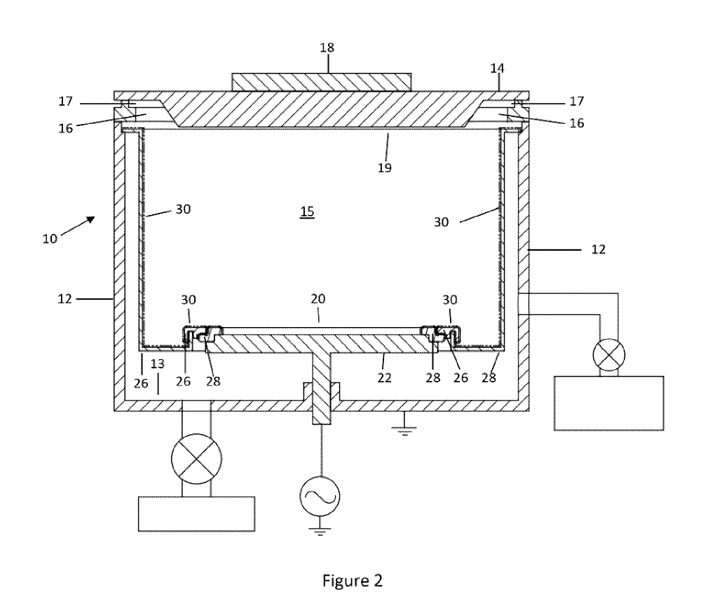

Referring to FIG. 2, the process chamber 10 is illustrated with the addition of a protective removable coating 30. The protective removable coating 30 may be applied to any surface within the process chamber 10 that may be exposed to excess material. In the illustration of FIG. 2, the protective removable coating 30 is applied to shielding components including the inner shield 24, the cover ring 26 and the deposition ring 28, a bonding surface of the removable coating 30 forming a releasable bond with the surface of the shielding components. As will be appreciated, these are the parts of the process chamber 10 that receives the bulk of the excess material, but other parts of the chamber may usefully be covered by the protective removable coating 30.

The protective removable coating 30 is a removable coating that may be applied over a surface exposed to excess material, such as the shielding components, and presenting a deposition surface to receive the excess material during a process run. In some aspects, the deposition surface may be specifically treated or formed to aid in reception, capture, and retention of the excess material. After completion of the process run, the removable coating 30 may be removed from the deposition surface 31 and, optionally, replaced with a fresh removable coating 30. As will be discussed below, the bond between the removable coating 30and the deposition surface 31 may be relatively weaker than either the bond between the excess material and the removable coating 30 and the bond between the excess material and the deposition surface 31.

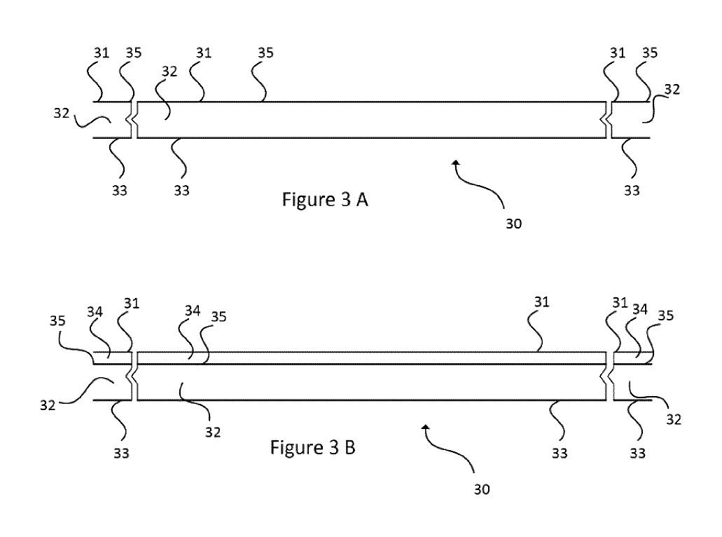

Referring to FIG. 3A, the removable coating 30 may be produced from a suitable sheet 32, such as a metal sheet (for instance: Al, Ti/TiN, Ta/TaN, Cu, Ni, Cr, Zn, SST, Alloys, Alumina (Al2O3), Aluminum nitride (AlN), Yttira (Y203), Alumina-Titania (Al203/TiO2), Yittira-Alumina (Y203/Al03)), Silicon Carbide, Silicon nitride (Si3N4), Quartz (SiO2), and other ceramics, which are standard materials used for constructing process chambers. The sheet 32 may have a varying thickness depending on a shape and configuration of the component to be covered but typically will be between 30 μm to 10 mm thick. In a first aspect, the removable coating 30 may comprise the sheet 32, a bonding surface 33 of the sheet 32 to be secured to the component by spot welding, presenting an exposed sheet surface 35 of the sheet 32 as a deposition surface 31 for receiving excess material. Preferably, the spot welding is selected to provide a minimal bond between the bonding surface 33 of the removable coating 30 and the component such that the removable coating 30 stays in place during light handling and operation of the process chamber, but is removable after the operational run life of the coated component. In some aspects, the sheet 32 may comprise a same material as the component. In other aspects, the sheet 32 may comprise a different material from the component.

In cases where the sheet is non-metallic, e.g. Quartz or ceramic, metal the non-metallic sheet may be formed around metal weld points that are exposed on the bonding surface 33 of the removable coating 30. The metal weld points provide attachment points for spot welding the non-metallic removable coating 30 to the component.

Referring to FIG. 3B, in a second aspect the removable coating 30 may further comprise a deposition layer 34 bonded to the sheet surface 35. The deposition layer 34 typically comprising a metal deposition onto the sheet surface 35, to improve retention and capture of excess material (for instance: Al, Ti, Ta, Cu, Ni, Cr, Zn, SST, and Alloys). In some aspects the deposition layer 34 may comprises a non-metallic material, to be bonded to the sheet surface 35. In some aspects, the coating may be comprised of a common material for each of the sheet 32 and the deposition layer 34.

The purpose of the deposition layer 34 is to provide a deposition surface 31 that is more receptive to receiving excess material than the sheet surface 35. The deposition layer 34 is fully bonded to the sheet 32, and of reduced thickness, typically ranging between 5 nm to 1000 μm. The deposition layer 34 may be produced, for instance, by anodizing, plasma coating, or spray coating the sheet 32 with the coating material. In some aspects, the deposition layer 34 may comprise a same material as the sheet 32. In some aspects, the deposition layer 34 may comprise a different material as the sheet 32. The deposition layer 34 provides for improved bonding with excess material over the sheet 32 alone, as it has been found that coating the sheet 32 with a deposition layer 34 provides for improved bonding of excess material over the sheet 32 alone.

Accordingly, a removable coating 30 may be selected for improved bonding characteristics for a given set of process conditions, e.g. excess material, without changing the composition of the underlying component to be protected. Furthermore, a plurality of removable coatings 30, each presenting a different deposition surface 31 may be provided to a manufacturing location. An appropriate removable coating 30 may be applied to shielding components for a specific process chamber run. Provision of removable coatings 30 having different deposition surfaces 31 allows for matching of a particular deposition surface 31 to a specific process chamber operational cycle, while using shielding components of a same composition.

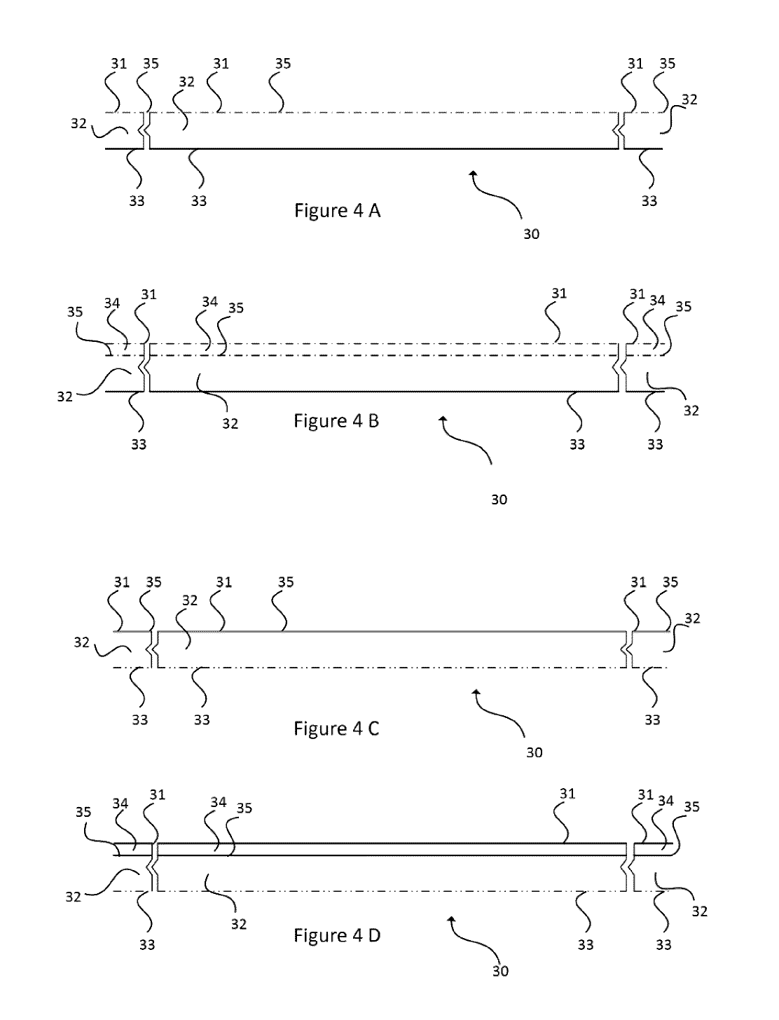

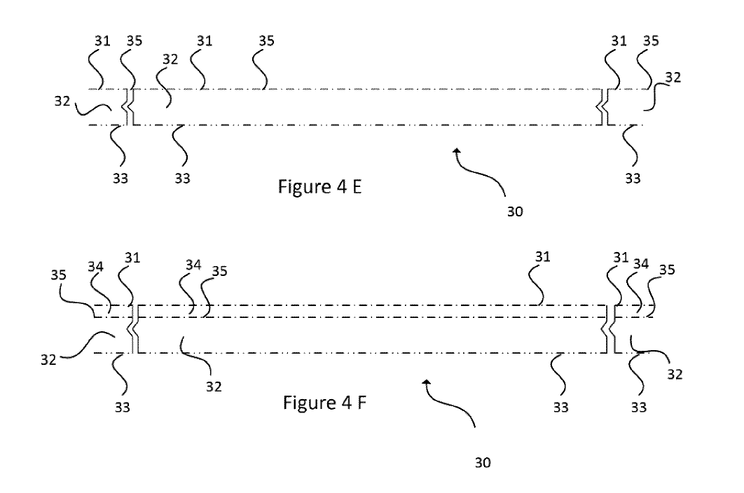

Referring to FIG. 4 A, in an aspect the removable coating 30 may further comprise a treatment or preparation applied to the deposition surface 31 to impart a deposition texture or desired surface roughness into the deposition surface 31. In the example of FIG. 4A, sheet surface 35 is treated to provide improved bonding for reception and retention of the excess material. The treatment may comprise, for instance, a treatment to provide a deposition texture exhibiting an increase in a roughness of the sheet surface 35 such as by bead blasting, etching, machining, or other means. In other aspects, where the removable coating 30 is ductile, the treatment may comprise a mechanical treatment applied to the sheet 32 to deform the sheet surface 35, for instance by rolling or pressing the sheet 32 with a patterned roller or press having a raised profile, to impress a pattern or irregular surface into the deposition surface 31 as the deposition texture.

Referring to FIG. 4B, the removable coating 30 comprises the sheet 32 and the deposition layer 34, with a treatment applied to the deposition surface 31 of the deposition layer 34. Depending upon the treatment applied, and the thickness of the deposition layer 34, the treatment may further deform the sheet surface 35, though it is not the deposition surface 31 in this embodiment. For example, where the sheet 32 and the deposition layer 34 are passed through a roller, one of the rollers may include a textured surface to impress a texture onto the deposition surface 31. Where the textured surface is of sufficient profile, both the deposition layer 34 and the sheet surface 35 of the sheet 32 may both be deformed to accommodate the profile.

Referring to FIGS. 4C and 4 D, in an aspect a similar treatment may be applied to the bonding surface 33 of the sheet 32 to impart a bonding texture in the bonding surface 33. In this case the treatment may be intended to provide reduced contact area between the bonding surface 33 and the shielding component. The reduced contact area may be useful, for instance, to provide a lower bonding force between the removable coating 30 and the component. The reduced contact area may also be useful to assist with temperature maintenance in the process chamber cavity 15 by providing a lower heat transfer rate between the removable coating 30 and the shielding component. In this fashion, the removable coating 30 may provide a measure of insulation to reduce a rate of heat transfer out of the process chamber cavity 15. For some processes the dynamics prefer a relatively slower heat transfer rate out of the process chamber cavity 15. For these processes, a removable coating 30 may be selected for both a material property to reduce heat transfer and/or a reduced coating contact area to reduce the contact between the removable coating 30 and an underlying shielding component. In cases where a relatively higher heat transfer rate is preferred, the bonding surface 33 may be relatively smooth, providing a relatively higher heat transfer rate.

The treatment may similarly comprise, for instance, a treatment to provide a bonding texture exhibiting an increase in a roughness of the bonding surface 33 such as by bead blasting, etching, or other means. In other aspects, the treatment may comprise a mechanical treatment applied to the sheet 32 to deform the bonding surface 33, for instance by rolling or pressing the sheet 32 with a patterned roller or press having a raised profile, to impress a pattern or irregular surface into the bonding surface 33 as the bonding texture. The bonding texture selected to affect at least one of a bonding between the bonding surface 33 and the shielding component to receive the coating, and a heat transfer rate between the removable coating 30 and the shielding component.

Referring to FIGS. 4 E and 4F, in an aspect a treatment may be applied to both the deposition surface 31 (and potentially the sheet surface 35), and the bonding surface 33. In this aspect, the treatment may comprise a same treatment applied to both of the opposed surfaces of the removable coating 30. In this aspect, the treating may alternately comprise a different treatment applied to both of the opposed surfaces of the coating.

According to another aspect of the invention, there is provided a process kit component comprising a base dimensioned to be positioned within a semiconductor process chamber with respect to an intended deposition substrate; and a removable coating 30 for shielding the base, the sheet comprising a metal sheet layer conforming to at least a portion of the base; and a coating layer affixed to and conforming to the metal sheet, the coating having a enhanced bonding strength between metal sheet layer and deposition material there across, wherein the removable coating 30 is selectively removable from the base.

Because the removable coating 30 is conformable, it can be selectively conformed to various shapes and configurations of an underlying shielding component. The removable coating 30 providing a deposition surface 31 receptive to excess material that can be relied upon to uniformly receive and “hold” the excess material, and the resultant deposition film build-up without immediate flaking of the film. Furthermore, a coated shielding component may be cleaned by simply removing and discarding the removable coating 30. A fresh coating 30 may be applied, providing a fresh deposition surface 31 for receiving excess material. Furthermore, the make-up of the deposition surface 31 may be tailored to a particular process. For instance, a process chamber running a copper process (i.e. using a copper target) can be shielded by a coating having a copper deposition surface 31. Conveniently, while a soft copper deposition surface 31 may be receptive to capturing copper excess material, the shielding components may be formed from another material, such as steel or titanium for durability. As compared with prior art methods for cleaning a process kit component whose actual surface is deposition surface that receives surface treatment by bead blasting or aluminum arc spraying, simply encapsulating the shielding component or a portion thereof, with a replacement coating 30 takes far less time to complete. As such, the coated shielding component can be quickly cleaned and put back into service. Furthermore, the removable coating 30 may optionally be applied to structural components of the process chamber 10 that may be partially exposed to excess material and require cleaning from time to time.

As explained above, a removable coating 30 may be provided with a deposition surface 31 matched to an intended excess material. Accordingly, a replacement coating 30 may have a similar roughness as the removable coating 30 it is replacing, or may have a different roughness depending on the type and thickness of an intended excess material. Various replacement removable coatings 30 may be made available in order to provide a selection of roughness levels for use in various stages of deposition where higher or lower stress excess material deposition films are being deposited. In embodiments where the deposition surface 31 comprises a treated surface, the extent of the roughness of a particular removable coating 30 can be tightly controlled, particularly where a mechanical process such as rolling or pressing is employed.

The removable coating 30 can be applied to any of the exposed surfaces within a process chamber 10.Shielding components comprising ceramic process kit components are typically manufactured with near-mirror smoothness surfaces. In an aspect where the removable coating 30 presents a ceramic deposition surface, the surface may be treated by modifying, for example by machining or bead blasting, at least a portion of the deposition surface to have an enhanced, generally-uniform roughness to improve bonding of excess material to the removable coating 30.

Although embodiments have been described with reference to the drawings, those of skill in the art will appreciate that variations and modifications may be made without departing from the spirit, scope and purpose of the invention as defined by the appended claims.

1. A removable coating for protecting process chamber components from excess material, comprising:
a sheet;
a bonding surface of the sheet for removable bonding to a process chamber component; and,
a deposition surface of the coating adapted to receive and retain the excess material.

2. The removable coating of claim 1, wherein the coating further comprises:
a deposition layer bonded to a sheet surface of the sheet in opposition to the bonding surface, the deposition layer providing the deposition surface.

3. The removable coating of claim 1, wherein the deposition surface has been treated to improve capture and retention of the excess material.

4. The removable coating of claim 3, wherein the treatment comprises at least one of:
rolling;
pressing; and,
machining.

5. The removable coating of claim 1, wherein the bonding surface has been treated to provide a bonding texture on the bonding surface for reducing a contact area between the sheet and the process chamber component.

6. The removable coating of claim 3, wherein the treatment comprises impressing a deposition texture into the deposition surface.

7. The removable coating of claim 5, wherein the treatment comprises rolling or pressing the coating to impress the bonding texture into the bonding surface.

8. The removable coating of claim 2 wherein the sheet is 30 μm to 10 mm thick, and wherein the deposition layer is 5 nm to 1000 μm thick.

9. The removable coating of claim 2, wherein the sheet and the deposition layer comprise a same material.

10. The removable coating of claim 2, wherein the sheet and the deposition layer comprise a different material.

11. The removable coating of claim 2, wherein the deposition layer comprises a metal.

12. The removable coating of claim 1, wherein the sheet comprises a metal sheet.

13. The removable coating of claim 1, wherein the removable bonding comprises spot welding the bonding surface to the process chamber component.

14. A process chamber comprising:
walls, base, and cover defining a process chamber cavity;
within the process chamber cavity, a pedestal and heater for supporting a substrate to receive a deposition material; and,
a removable coating comprising:
a sheet;
a bonding surface of the sheet releasably bonded to at least one interior surface of the process chamber; and,
a deposition surface of the sheet for capturing and retaining the excess material;
wherein the bonding surface of the removable coating is releasably bonded to at least one interior surface of the process chamber, the removable coating adapted to receive, capture and retain excess material resulting from operation of the process chamber, and adapted to be removed from the at least one interior surface by breaking the releasable bond between the removable coating and the at least one interior surface while maintaining the bond between the deposition surface and the retained excess material to allow removal of the removable coating and retained excess material from the process chamber.

15. The process chamber of claim 13, wherein the at least one interior surface comprises a shielding component within the process chamber cavity located to shield an interior wall surface of the process chamber from the excess material.

16. The process of claim 13, wherein the sheet comprises a metal sheet.

17. A method for coating a process chamber component comprising:
providing a removable coating for protecting the process chamber component from excess material, the removable coating comprising:
a sheet;
a bonding surface of the sheet for bonding to a process chamber component; and,
a deposition surface of the coating adapted to receive and retain the excess material; and,
releasably bonding the removable coating by conforming the removable coating to a surface of the process chamber component intended to be protected, and spot welding the removable coating to the process chamber component.

18. (canceled)

19. (canceled)

20. (canceled)

21. (canceled)

22. (canceled)

23. (canceled)

24. (canceled)

25. The method of claim 17, wherein the coating further comprises:
a deposition layer bonded to a sheet surface of the sheet in opposition to the bonding surface, the deposition layer providing the deposition surface.

26. The method of claim 17, wherein the deposition surface has been treated to improve capture and retention of the excess material.

27. The method of claim 26, wherein the treatment comprises at least one of:
rolling;
pressing; and,
machining.
